(19) United States
(12) Patent Application Publication
(10) Pub. No.: US 2012/0320501 A1
(43) Pub. Date: Dec. 20, 2012

(54) PROTECTIVE COVER

(76) Inventor: Andrew Ackloo, Toronto (CA)

(21) Appl. No.: 13/329,967

(22) Filed: Dec. 19, 2011

Related U.S. Application Data
(60) Provisional application No. 61/424,443, filed on Dec. 17, 2010.

(51) Int. Cl. H05K 7/00; B29C 65/00; B29C 69/00

(52) U.S. Cl. 361/679.01; 264/241; 156/91

(57) ABSTRACT

Disclosed is a protective cover for a portable electronic device that includes a flexible cushioning cover, as well as a hard plastic removable cover to protect the touch screen of the portable electronic device. The plastic screen cover covers substantially all of the touch screen, while allowing a user to access a portion of the touch screen to answer an incoming call. The screen cover can remain in place while answering an incoming call to provide protection of the touch screen and allow the user to quickly answer incoming calls.

### CROSS-REFERENCE TO RELATED APPLICATION

The present application is based upon and claims the benefit of U.S. Provisional Patent Application Ser. No. 61/424,443, filed Dec. 17, 2010, by, entitled “Protective Cover,” which application is hereby specifically incorporated herein by reference for all that it discloses and teaches.

### BACKGROUND OF THE INVENTION

Protective covers are used on various different types of electronic devices to provide protection for these devices. Handheld and portable electronic devices include, but are not limited to, mobile phones, computers, including handheld computers, tablet computers and ultra mobile computers, MP3 players, video players, smart phones, walkie-talkies, navigation devices, such as GPS devices, telematics devices, cell phones, satellite phones, pagers, monitors, bar code scanners, and various hybrid devices that combine two or more of these functions. Handheld and other portable electronic devices often use touch screens and interactive panels, including, but not limited to, capacitive coupled interfaces and other interactive touch screen controls. Due to the sensitive nature of many handheld and portable electronic devices, it is desirable to provide protection for these devices.

### SUMMARY OF THE INVENTION

An embodiment of the present invention may therefore comprise a protective cover for a portable electronic device having a touch screen comprising: a screen cover comprising: a substantially transparent front panel that is adapted to substantially cover and protect the touch screen when the screen cover is disposed over the touch screen, the front cover having a thickness that substantially prevents user inputs from being transmitted to the touch screen; an actuation port disposed on the front panel that is adapted to transmit user inputs to an actuation area on the touch screen when the screen cover is placed on the touch screen; a flexible cushioning cover comprising: a front portion having an opening that is adapted to allow the screen cover to be placed over the touch screen so that the front panel is recessed in the opening on the front portion of the flexible cushioning cover and the actuation port is substantially aligned with an actuation area on the touch screen; a recessed area on a back portion of the flexible cushioning cover having a size and shape that substantially matches the front panel so that the screen cover can be placed in the recessed area for storage when not disposed over the touch screen.

An embodiment of the present invention may further comprise a method of making a protective cover for a touch screen of a portable electronic device comprising: making a screen cover from a clear plastic material comprising: forming a substantially transparent front panel that is adapted to cover at least a substantial portion of the touch screen; forming at least two arms that are attached to the front panel and that extend substantially perpendicular to the front panel; forming clips on end portions of the arms; forming an actuation port in the front panel that is adapted to transmit user inputs to the touch screen when the screen cover is placed over the touch screen.

An embodiment of the present invention may further comprise a method of protecting a touch screen of a portable electronic device comprising: obtaining a screen cover that is made from a clear plastic material comprising: a substantially transparent front panel that is adapted to substantially cover and protect the touch screen when the screen cover is disposed over the touch screen, the front cover having a thickness that substantially prevents user inputs from being transmitted to the touch screen; an actuation port disposed on the front panel that is adapted to transmit user inputs to an actuation area on the touch screen when the screen cover is placed on the touch screen; obtaining a flexible cushioning cover that substantially surrounds the portable electronic device, the flexible cushioning cover comprising: a front portion having an opening formed in the front portion; a recessed area on a back portion of the flexible cushioning cover that has a size and shape that substantially matches the front panel; placing the flexible cushioning cover on the electronic device so that the opening in the front portion of the flexible cushioning cover is aligned with the touch screen; placing the screen cover over the opening in the front portion of the flexible cushioning cover so that the screen cover is disposed over the touch screen and recessed in the opening, and the actuation port is aligned with an actuation area on the touch screen to transmit user inputs to the actuation area; removing the screen cover from the opening and placing the screen cover in the recessed area on the back portion of the flexible cushioning cover to store the screen cover when the screen is not disposed to protect the touch screen.

### BRIEF DESCRIPTION OF THE DRAWINGS

FIG. 1 is a perspective, front exploded view of one embodiment of a protective cover.

FIG. 2 is a front perspective view of the assembled protective cover illustrated in the embodiment of FIG. 1.

FIG. 3 is a back perspective, exploded view of the embodiment of FIGS. 1 and 2.

FIG. 4 is a back assembled perspective view of the embodiments of FIGS. 1, 2 and 3.

### DETAILED DESCRIPTION OF THE EMBODIMENTS

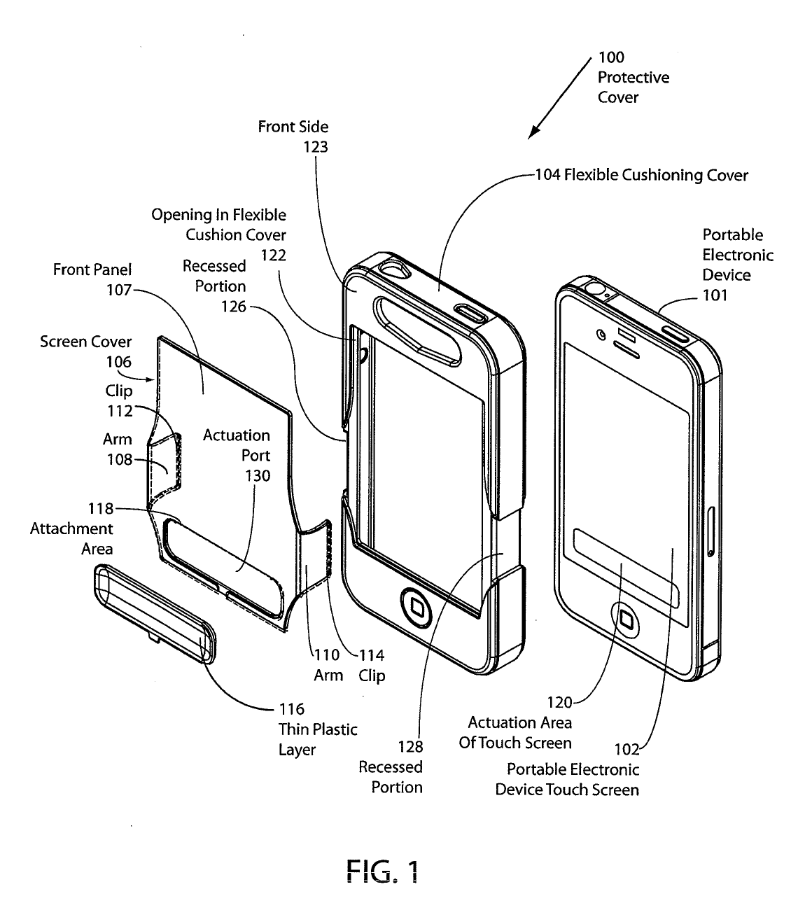

FIG. 1 is a front perspective, exploded view of a protective cover 100 that surrounds a portable or handheld electronic device 101. The portable electronic device 101 has a touch screen 102 for displaying and entering data. The touch screen comprises an electronic visual display that detects the presence and location of a touch within a display area. Touch screens allow a user to interact directly with the information that is displayed on the screen, rather than indirectly through an intermediate device. As such, touch screens can be sensitive to the environmental surroundings in which the portable electronic device is disposed. There are various types of touch screens that have varying degrees of sensitivity and fragility. Capacitive touch screen panels utilize an insulator, such as glass, which is coated with a transparent conductive material, such as indium tin oxide. Since the human body is a conductor, touching of the surface of the screen results in distortion of the screen's electrostatic field, which can be measured as a change in capacitance. Various technologies are used to locate the position of the change in capacitance on the screen. Once the location is identified, the information is sent to a controller for processing.

Since there are numerous different types of touch screens, touch screens have different responses to different types of inputs and different sensitivities to impacts, abrasions and other environmental conditions that can possibly harm the touch screen. Thin film screen protectors can assist in retardation of abrasions and scratches. Thin film screen protectors do not, however, protect a touch screen from breakage or cracking as a result of impacts, drop situations, gouges or other types of blows that can actually break or damage the touch screen material itself. Further, thin film screen protectors purposefully allow the touch screen to be continually utilized while the thin film screen protector is in place. As a result, many inadvertent inputs are made using touch screen mobile phones that use screen protectors, rather than protective screen covers.

Many portable electronic devices include an actuation area 120 that provides a mechanism on the touch screen for activating the portable electronic device 101. For example, on some types of phones, such as the iPhone® that is sold by Apple Corporation, a slide arrow portion is used in the actuation area 120 on the touch screen 102 to activate the portable electronic device 101 to perform functions, such as answering incoming calls and generating displays on the touch screen 102. To operate the slide arrow portion, the user slides a finger across the actuation area 120, which is received as a series of capacitive entries on the touch screen 102, that initiate the display and allow a user to answer an incoming call.

As also shown in FIG. 1, a flexible cushioning cover 104 is provided that substantially surrounds the portable electronic device 101. The flexible cushioning cover 104 can be made of soft silicon or other materials mentioned below that provide a cushioning effect in drop situations, or other impact situations. Flexible cushioning cover 104 may be made from a soft silicon material having a density and softness that is sufficient to absorb shocks in drop situations and other impact situations. The flexible cushion cover may also be made from silicon, PVC and other materials that share similar physical properties. Flexible cushioning cover 104 has various openings and various molded pieces that are adapted for the specific type of phone to be protected. The portable electronic device 101, as well as the flexible cushioning cover 104 and screen cover 106, are adapted to fit the portable electronic device 101. As shown in FIG. 1, there is a large opening 122 on the front side 123 of flexible cushion cover 104, which allows the portable electronic device 101 to be inserted into the flexible cushioning cover 104. The opening 122 allows a user to access the full touch screen 102 of the portable electronic device 101 when the portable electronic device 101 is inserted into the flexible cushioning cover 104.

The thickness of the cushioning cover 104, illustrated in FIG. 1, causes the flexible cushioning cover 104 to be elevated around the edges of the touch screen 102. Although the edges of the flexible cushion cover 104 provide some impact protection for the touch screen 102, direct protection of the touch screen 102 is not provided with typical one-piece flexible cushioning covers. As also illustrated in FIG. 1, the flexible cushioning cover 104 has recessed portions 126, 128 on both sides of the flexible cushioning cover 104, that allow the screen cover 106 to be easily attached to flexible cushioning cover 104.

Screen cover 106, as illustrated in FIG. 1, is a separate piece of transparent plastic material, such as polycarbonate, PVC, ABS, acrylic, PP, nylon, PMMA, HDPE, TPE, TPR, silicon or other materials having similar physical properties, that provides protection to the touch screen 102 of the portable electronic device 101 from impacts, abrasions, blows, and other potential damage that may be caused to the touch screen 102. Screen cover 106 has arms 108, 110 on each side of a clear, transparent front panel 107. Arms 108, 110 have clips 112, 114, respectively, that are attached to end portions of the arms 108, 110. Screen cover 106 is sufficiently thick to provide a high degree of protection to touch screen 102, while remaining sufficiently thin to substantially form a substantially flush layer with the outer surface of the flexible cushioning cover 104 around opening 122 to provide a compact protective cover 100. In addition, the screen cover 106 is made so that touch screen inputs are not transmitted through the screen cover 106. As such, accidental inputs are not transmitted to touch screen 102. For example, users of the portable electronic device 101 may place the portable electronic device 101 in a pocket, purse or other location, where an accidental input may occur to the touch screen 102, such as an accidental call. The screen cover 106 is sufficiently thick, or a material is used for the screen cover to substantially prevent accidental inputs to the touch screen 102 from occurring. Arms 108, 110 may have the same thickness as the screen cover 106, or may be slightly thinner, so that arms 108, 110 fit within the recessed portions 126, 128 on the sides of the flexible cushioning cover 104, to provide a substantially flush surface when the screen cover 106 is disposed on the flexible cushioning cover 104.

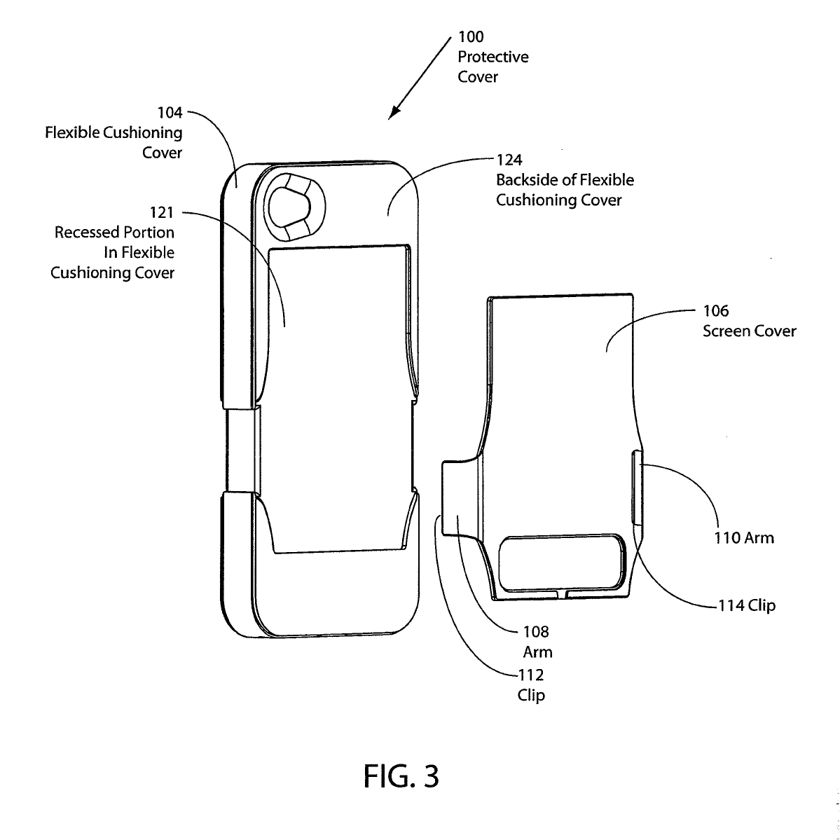

In operation, the portable electronic device 101 is slid in the opening 122 on the front of the flexible cushioning cover 104. The flexible cushioning cover 104 stretches to allow the portable electronic device to fit in the opening 122. As indicated above, the density of the material of the flexible cushioning cover 104 is sufficient to allow the flexible cushioning cover 104 to stretch and resume its original shape, especially along the edges of the opening 122, while providing sufficient cushioning to the portable electronic device 101. Screen cover 106 can then be placed over touch screen 102, so that arms 108, 110 fit in recessed portions 126, 128 and clips 112, 114 clip to the backside 124 (FIG. 3) of a flexible cushioning cover 104. The screen cover 106 can also be placed on the backside of the flexible cushioning cover 104 when not in use.

When the screen cover 106 is placed over the touch screen 102, the screen cover 106 is coextensive with the touch screen 102 and, as such, provides protection to the surface of the touch screen 102. As indicated above, the screen cover 106 has a thickness and/or is made of a material that, in combination, prevent inputs to the touch screen 102, while the screen cover 106 is in place over the touch screen 102. For example, since the surface of the touch screen 102 is covered, interactions with substantially all of the functions of the portable electronic device 101 are prevented by a user.

Smart phones, as one example of a portable electronic device 101, provide a multi-functional platform for communication through telephone calls, texting, interne access, and other functions. A substantial portion of the use of smart phones, however, continues to be voice telephone calls. It is therefore advantageous to continue to provide a high degree of protection to the touch screen 102 of a portable electronic device 101 during cell phone call operation. Typically, silicon type cushioning covers are used in conjunction with screen protectors, that are a very thin plastic piece that adheres to the touch screen 102. While screen protectors provide some protection against scrapes and abrasions that may occur to the touch screen 102, essentially no protection is provided by screen protectors for impacts. As such, it is desirable to provide protection to a touch screen 102 while still allowing a user to answer calls without the necessity of removing a protective screen cover, such as screen cover 106. In accordance with one embodiment, an opening can be provided in actuation port 130 in the screen cover 106. The opening can be covered by a thin plastic layer 116 that is attached in the attachment area 118 around the edges of the actuation port 130 of the screen cover 106. The thin plastic layer may be made from a material such as TPU, or a similar material, that transmits touches to allow the user to input data through the actuation port 130.

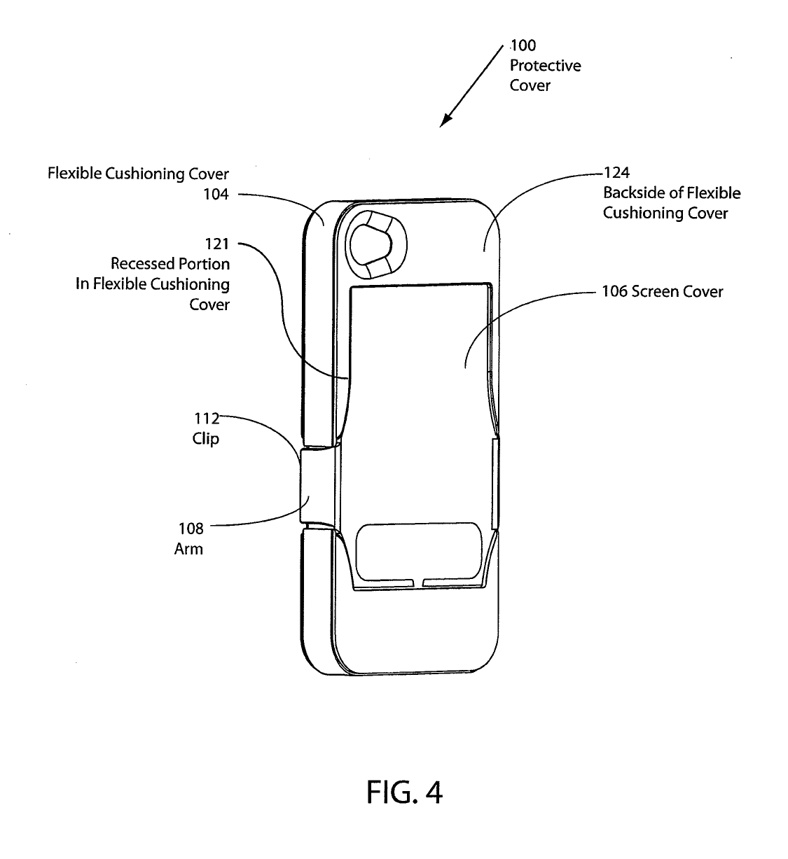

In the embodiment illustrated in FIG. 1, the thin plastic layer 116 is attached in the attachment area 118 of the screen cover 106. The attachment area 118 may be the area surrounding actuation port 130 around the inner surface of the screen cover 106. Alternatively, the attachment area 118 may be the area surrounding the actuation port 130 on the outer surface of screen cover 106. The thin plastic layer 116 is sufficiently thin and/or flexible to allow a user to generate an input on the touch screen 102. In the case of an Apple iPhone® 4, capacitive inputs are read by the touch screen 102. Hence, a material that is sufficiently thin and that allows a capacitive input to be transmitted through the thin plastic layer 116 can be used, such as many types of TPU thin film plastics. For example, thin plastic layer 116 may comprise a TPU having a thickness of approximately 0.010″ or less. Since there are many different types of touch screens, different materials having different densities, electrical conductivity and flexibility can be used depending upon the type of touch screen that is utilized in the portable electronic device 101. For example, PVC or silicon may be used that has a cross-sectional thickness that allows interactibility. In the embodiment illustrated in FIG. 1, an iPhone® 4 is illustrated, in which a slide arrow must be accessed by a user in order to answer a call. Thin plastic layer 116 allows a user to slide a finger along the thin plastic layer 116, so that the actuation area 120 on the touch screen 102 is accessed and the user input is read by the actuation area 120, so that a call can be answered. In this manner, the screen cover 106 does not have to be removed during the rapid process of answering a call on the portable electronic device 101. Since the user does not have to remove the screen cover 106 to answer a call, many missed calls are prevented. At the same time, the user is able to provide a high degree of protection to the touch screen 102, while still being able to answer calls. When the user desires to have full access to the touch screen 102, the user can remove the screen cover 106 and place it on the backside 124 of the flexible cushioning cover 104, as explained in more detail below with respect to FIGS. 3 and 4.

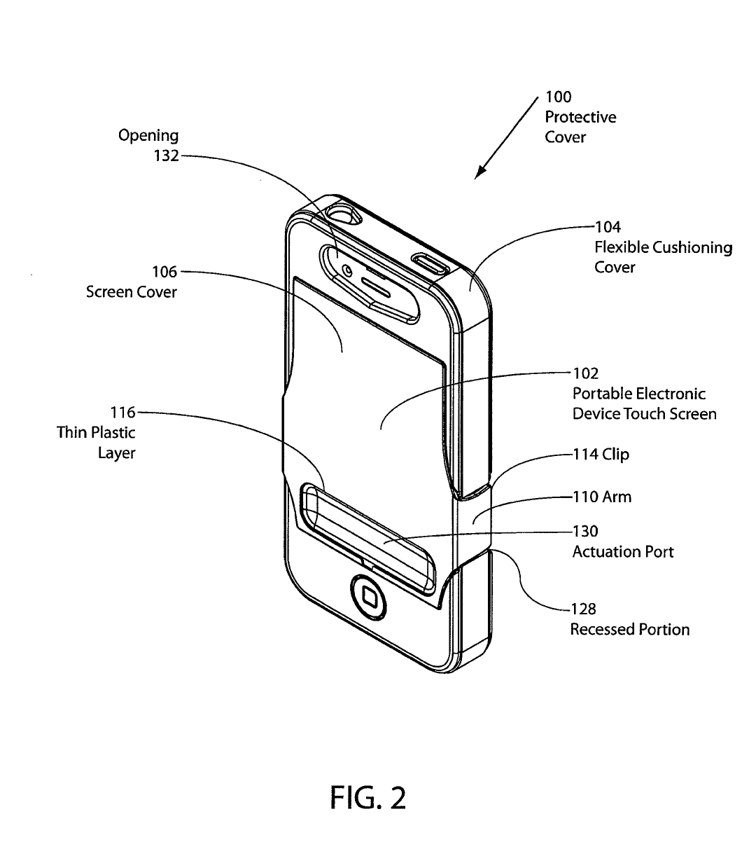

The thin plastic layer 116, illustrated in FIGS. 1 and 2, can be attached to the screen cover 106 along the attachment area 118 in any desired manner. For example, any type of bonding techniques can be used, including ultrasonic welding and other bonding techniques. Also, chemical adhesives and other bonding materials can be employed to attach the thin plastic layer 116 to the screen cover 106. Alternatively, over-molding techniques can be utilized to over-mold a thin plastic layer 116 to cover the actuation port 130. Further, actuation port 130 may simply be an area in the screen cover 106 that has a reduced thickness that is sufficiently thin to allow inputs from a user to be transmitted to the touch screen 102. Again, the material utilized for the screen cover 106 can be selected to provide the desired amount of protection to the touch screen 102, while still allowing inputs to be transmitted through a thin layer of the screen protector material located in the actuation port 130. For example, if polycarbonate is used for the screen cover 106, the polycarbonate material can have a reduced thickness in the area of the actuation port 130, which is sufficiently thin to allow capacitive inputs to be transmitted to a capacitive touch screen, such as capacitive touch screen of an iPhone®. Thickness of approximately 0.010″ allows transmission of capacitive inputs through polycarbonate. Other types of materials, such as PVC, ABS, TPE, TPR, HDPE, acrylic, PP, nylon, PMMA, silicon, and other materials that share similar physical properties, can be used. A number of these materials are more flexible than polycarbonate and would allow a thin layer in the area of the actuation port 130 to be deflected and, as such, generate an input to a touch screen that reads pressure inputs. Thicknesses and materials suitable for a capacitive coupling interface are disclosed in U.S. Pat. Nos. 6,646,864, 6,995,976, 7,158,376 and 7,180,735, which are specifically incorporated herein by reference for all that they disclose and teach.

FIG. 2 is a schematic assembly perspective front view of the protective cover 100 of the embodiment of FIG. 1 in an assembled condition. As shown in FIG. 2, screen cover 106 is placed over the touch screen 102 and substantially covers the surface of the touch screen 102, except for the actuation port 130, which allows a user to access the actuation area 120 to answer incoming calls in a quick and easy manner. As also shown FIG. 2, opening 132 in the flexible cushioning cover 104 allows users access to the earphone to listen to incoming calls. An opening (not shown) in the flexible cushioning cover 104 is provided for the microphone of the portable electronic device 101, so that the user may speak into the portable electronic device 101 to respond to incoming calls. As also shown in FIG. 2, arm 110 fits in the recessed portion 128 and has a thickness that creates a substantially flush surface with the flexible cushioning cover 104. Clip 114 attaches to the backside 124 (FIG. 3) of the flexible cushioning cover 104.

As disclosed above, a user can easily answer an incoming call by sliding a finger over the thin plastic layer 116 so that the actuation area 120 of the touch screen 102 is accessed by the user through the actuation port 130 to answer the call with the screen cover 106 in place. The user can listen and respond verbally to incoming calls, with the screen cover 106 in place, since the screen cover 106 does not cover portions of the earphone or microphone of the portable electronic device 101. With the screen cover 106 in place, the protective cover 100 that covers the portable electronic device 101 can be inserted in and removed from a pocket or purse, or other location, and provide a high degree of protection for the touch screen 102, while allowing quick and easy access to incoming calls. Further, since the material of the screen cover 106 is normally a harder and smoother material than the flexible cushioning cover 104, the screen cover 106 assists in allowing the protective cover 100 to be pulled from a pocket in a quick and easy fashion, without turning the pocket inside out, and without scattering the valuable contents in the pocket.

FIG. 3 is a schematic illustration of the backside of the embodiment of the protective cover 100, illustrated in FIGS. 1 and 2. As shown in FIG. 3, the flexible cushioning cover 104 has a recessed portion 121 on the backside 124. The recessed portion 121 matches the shape of the screen cover 106 so that the screen cover 106 can be placed on the backside 124 when not in use. In other words, recessed portion 121 comprises a storage area for the screen cover 106 when the screen cover 106 is not placed over the touch screen 102 of the portable electronic device 101, as illustrated in FIGS. 1 and 2. Arm 108 fits in the recessed portion 128, while arm 110 fits in the recessed portion 126 of the flexible cushioning cover 104. Clips 112, 114 clip to a front portion of the recessed portions 128, 126, respectively. Since the screen cover 106 is a separate piece, it can be awkward to find a place to store the screen cover 106 when not in use over the touch screen 102. Without a convenient place to store the screen cover 106, the screen cover can be easily lost, misplaced, or not used to protect the touch screen 102 if not stored in a convenient location. The ability to store the screen cover 106 in a recessed portion 121 on the backside 124 of the flexible cushioning cover 104 allows the screen cover 106 to be stored conveniently, removed and replaced over the display screen of the portable electronic device 101 in a quick and convenient manner. In addition, storage of the screen cover 106 on the backside 124 of the flexible cushioning cover provides a smooth surface for protective cover 100, which allows removal from a user's pocket without turning the user's pocket inside out.

FIG. 4 is a schematic, perspective assembled view of the embodiment illustrated in FIGS. 1, 2 and 3. As illustrated in FIG. 4, the screen cover 106 is placed in the recessed portion 121 and is substantially flush with the backside 124 of the flexible cushioning cover 104. Clip 112, which is attached to arm 108, holds the screen cover 106 securely to the backside 124 of the protective cover 100 in the recessed portion 121. As such, the screen cover 106 can be conveniently stored in a secure manner on the backside 124 of the protective cover 100 when the screen cover 106 is not disposed over the touch screen 102. Screen cover 106 can be easily removed and placed over the front side of the flexible cushioning cover 104 when desired, to provide protection to the touch screen 102. Since the screen cover 106 is made from a hard plastic material that has a smooth surface, the screen cover 106 assists in allowing the protective cover 106 to be inserted in, and removed from, a pocket without turning the pocket inside out. The recessed portion 121 allows the screen cover 106 to be substantially flush with the backside 124 of the flexible cushioning cover 104.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A protective cover for a portable electronic device having a touch screen comprising:
a screen cover comprising:
a substantially transparent front panel that is adapted to substantially cover and protect said touch screen when said screen cover is disposed over said touch screen, said front cover having a thickness that substantially prevents user inputs from being transmitted to said touch screen;
an actuation port disposed on said front panel that is adapted to transmit user inputs to an actuation area on said touch screen when said screen cover is placed on said touch screen;
a flexible cushioning cover comprising:
a front portion having an opening that is adapted to allow said screen cover to be placed over said touch screen so that said front panel is recessed in said opening on said front portion of said flexible cushioning cover and said actuation port is substantially aligned with an actuation area on said touch screen;
a recessed area on a back portion of said flexible cushioning cover having a size and shape that substantially matches said front panel so that said screen cover can be placed in said recessed area for storage when not disposed over said touch screen.

2. The protective cover of claim 1 wherein said actuation port comprises:
a thin plastic layer disposed over an opening in said front panel.

3. The protective cover of claim 1 wherein said actuation port comprises:
a layer of plastic that is molded over an opening in said front panel.

4. The protective cover of claim 1 wherein said actuation port comprises:
a portion of said front panel that is sufficiently thin to allow transmission of user inputs to said touch screen.

5. A method of making a protective cover for a touch screen of a portable electronic device comprising:
making a screen cover from a clear plastic material comprising:
forming a substantially transparent front panel that is adapted to cover at least a substantial portion of said touch screen;
forming at least two arms that are attached to said front panel and that extend substantially perpendicular to said front panel;
forming clips on end portions of said arms;
forming an actuation port in said front panel that is adapted to transmit user inputs to said touch screen when said screen cover is placed over said touch screen.

6. The method of claim 5 further comprising:
making a flexible cushioning cover that is adapted to substantially surround said portable electronic device comprising:
forming an opening on a front portion of said flexible cushioning cover;
forming a recessed area on a back portion of said flexible cushioning cover having a size and shape that substantially matches said screen cover so that said front panel substantially covers and protects said touch screen and is recessed in said opening on said front portion of said flexible cushioning cover and aligned with said touch screen when said flexible cushioning cover and said screen cover are placed on said portable electronic device;
forming recessed areas on side portions of said flexible cushioning cover having a size and shape that substantially matches said arms so that said arms are recessed in said side portions of said flexible cushioning cover when said arms are disposed on said flexible cushioning cover;
said recessed area on said back portion and said recessed areas on said side portions providing a storage area for said screen cover when said screen cover is not disposed over said touch screen.

7. The method of claim 6 wherein said process of forming an actuation port comprises:
forming an opening in said front panel;
attaching a thin plastic layer over said opening that is capable of transmitting user inputs.

8. The method of claim 6 wherein said process of forming an actuation port comprises:
forming an opening in said front panel;
molding a layer of substantially transparent plastic over said opening.

9. The method of claim 6 wherein said process of forming an actuation port comprises:
forming a portion of said front panel that is sufficiently thin to transmit user inputs to said touch screen.

10. A method of protecting a touch screen of a portable electronic device comprising:
obtaining a screen cover that is made from a clear plastic material comprising:
a substantially transparent front panel that is adapted to substantially cover and protect said touch screen when said screen cover is disposed over said touch screen, said front cover having a thickness that substantially prevents user inputs from being transmitted to said touch screen;
an actuation port disposed on said front panel that is adapted to transmit user inputs to an actuation area on said touch screen when said screen cover is placed on said touch screen;
obtaining a flexible cushioning cover that substantially surrounds said portable electronic device, said flexible cushioning cover comprising:
a front portion having an opening formed in said front portion;
a recessed area on a back portion of said flexible cushioning cover that has a size and shape that substantially matches said front panel;
placing said flexible cushioning cover on said electronic device so that said opening in said front portion of said flexible cushioning cover is aligned with said touch screen;
placing said screen cover over said opening in said front portion of said flexible cushioning cover so that said screen cover is disposed over said touch screen and recessed in said opening, and said actuation port is aligned with an actuation area on said touch screen to transmit user inputs to said actuation area;
removing said screen cover from said opening and placing said screen cover in said recessed area on said back portion of said flexible cushioning cover to store said screen cover when said screen is not disposed to protect said touch screen.

11. The method of claim 10 further comprising:
attaching said screen cover to said flexible cushioning cover using clips.

12. The method of claim 10 further comprising:
forming said actuation port as an opening in said front panel;
attaching a thin plastic layer over said opening, said thin plastic layer being capable of transmitting user inputs.

13. The method of claim 10 further comprising:
forming said actuation port as an opening in said front panel;
molding a layer of substantially transparent plastic over said opening.

14. The method of claim 10 further comprising:
forming said actuation port by creating an area of reduced thickness on said front panel that is sufficiently thin to transmit user inputs.
